(19) United States
(12) Patent Application Publication
(10) Pub. No.: US 2024/0426874 A1
(43) Pub. Date: Dec. 26, 2024

(54) SPACE TRANSFORMER SUPPORT STRUCTURE AND AN ELECTRICAL CONNECTION DEVICE

(71) Applicant: Kabushiki Kaisha Nihon Micronics, Tokyo (JP)

(72) Inventor: Ken HASEGAWA, Aomori (JP)

(21) Appl. No.: 18/747,175

(22) Filed: Jun. 18, 2024

(30) Foreign Application Priority Data
Jun. 22, 2023 (JP) 2023-102247

(51) Int. Cl. G01R 1/073

(52) U.S. Cl. CPC G01R 1/07378

(57) ABSTRACT

A space transformer support structure that supports a space transformer interposed between a printed board and a probe head includes a guide plate provided on a side of the probe head of the space transformer and supporting the lower surface of the space transformer, and connecting members that fixes the guide plate to the printed board. A plurality of protrusions in point contact with the lower surface of the space transformer is provided on the surface of the guide plate.

### CROSS-REFERENCE TO RELATED APPLICATIONS

The present application is based on, and claims priority from Japanese Patent Application No. 2023-102247, filed on Jun. 22, 2023, the entire contents of which are incorporated herein by reference.

### TECHNICAL FIELD

The present disclosure relates to a space transformer support structure and an electrical connection device.

### BACKGROUND ART

In order to measure electrical characteristics of an object to be inspected such as a semiconductor integrated circuit, an electrical connection device is used, which includes a probe contacted with the object to be inspected. An electrical connection device is configured such that a probe head for holding a probe is mounted on a printed circuit board on which lands are arranged that are electrically connected to the probe.

Each probe held by the probe head is contacted with a wafer pad of the object to be inspected, so that the electrical characteristics of the object to be inspected can be measured. Further, a space transformer is arranged between the probe head and the printed circuit board to convert a wiring pitch between each probe and the printed circuit board.

The space transformer is fixed by a fixing member connected to the printed circuit board, and the probe head is fixed to the space transformer (see Patent Literature 1: WO2007/078493A1). Therefore, the electrical characteristics of the object to be inspected are measured in a state in which the printed circuit board, the space transformer, and the probe head are fixed to each other.

### SUMMARY

However, in the space transformer support structure described in Patent Literature 1, there is a problem that it is difficult to align the probe with the wafer pad since the printed circuit board, the probe head, and the space transformer are fixed to each other. In particular, there is a problem that the alignment becomes more difficult when the measurement is carried out by an electrical connection device configured using the space transformer supplied by someone or other.

The present disclosure is made to solve such conventional problems, and an object of the present disclosure is to provide a space transformer support structure and an electrical connection device capable of easily performing the alignment of the probe with the wafer pad.

A space transformer support structure according to one aspect of the present disclosure that supports a space transformer interposed between a printed circuit board and a probe head, includes a guide plate provided on a side of the probe head of the space transformer and supporting a first surface of the space transformer; and a connecting member that fixes the guide plate to the printed circuit board. A plurality of protrusions in point contact with the first surface of the space transformer are provided on the surface of the guide plate.

An electrical connection device according to one aspect of the present disclosure includes: a printed circuit board; a probe head that holds a plurality of probes, each of the probes having a base end electrically connected to the printed circuit board and a tip end contacted with an object to be inspected; a space transformer interposed between the printed circuit board and the probe head and converting a wiring pitch of each of the probes; a guide plate provided on a side of the probe head of the space transformer and supporting a first surface of the space transformer; and connecting members that fix the guide plate to the printed circuit board. A plurality of protrusions in point contact with the first surface of the space transformer is provided on the surface of the guide plate.

According to the present disclosure, alignment of the probe with the wafer pad can be easily performed.

### BRIEF DESCRIPTION OF THE DRAWINGS

FIG. 1 is a cross-sectional view illustrating a configuration of an electrical connection device to which a support structure according to an embodiment is applied.

FIG. 2 is an enlarged view of an “A” section illustrated in FIG. 1.

FIG. 3 is a cross-sectional view cut by I-I illustrated in FIG. 1.

FIG. 4 is an illustration schematically illustrating an example of protrusions formed in a ball bearing shape.

FIG. 5 is an illustration schematically illustrating an example of protrusions formed in a vertical curved shape.

FIG. 6 is an illustration illustrating an example with four protrusions.

FIG. 7 is an illustration illustrating an example wherein bolts connecting a printed circuit board and a guide plate are differential screws.

### DETAILED DESCRIPTION

Embodiments will be described with reference to the drawings. In the description of the following drawings, the same or similar parts are denoted by the same or similar reference numerals. However, it should be noted that the drawings are schematic, and the proportions of the dimensions of each part are different from those of the actual drawings. Needless to say, there are portions of the drawings that differ in their dimensional relationships and ratios. The following embodiments illustrate devices for embodying the technical concepts of the present disclosure, and the embodiments do not specify the materials, shapes, structures, arrangements, and the like of the components as described below.

### DESCRIPTION OF EMBODIMENTS

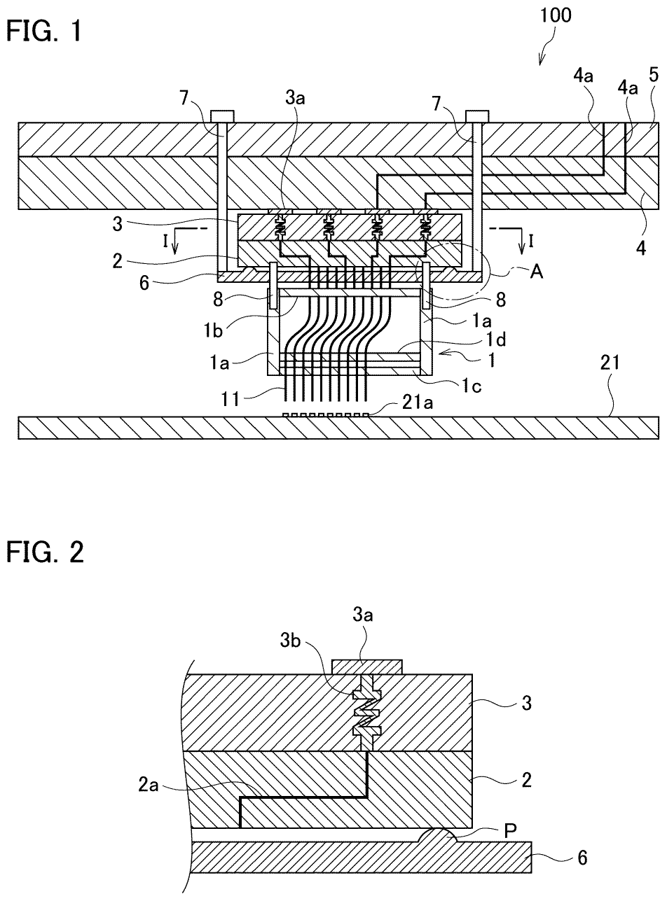

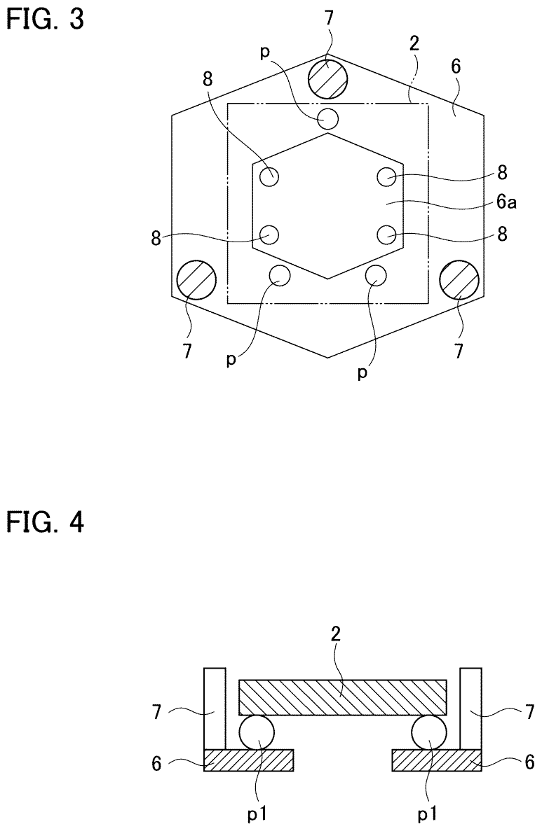

FIG. 1 is a cross-sectional view illustrating a configuration of an electrical connection device 100 to which a space transformer support structure according to an embodiment is applied. FIG. 2 is an enlarged view of the “A” section illustrated in FIG. 1. FIG. 3 is a cross-sectional view cut by I-I illustrated in FIG. 1.

As illustrated in FIG. 1, the electrical connection device 100 includes a probe head 1, a space transformer 2, an interposer 3, a printed circuit board 4, a reinforcing plate 5, and a guide plate 6. In the following description, a side of the reinforcing plate 5 (upper side in FIG. 1) is an upward direction, and the opposite side (lower side in FIG. 1) is a downward direction. A direction of a plane perpendicular to a vertical direction is a plane direction.

A plurality of probes 11 is held in the probe head 1. A tip end of each probe 11 is connected to each pad 21a of a wafer 21 as an object to be inspected. That is, the probe head 1 and the wafer 21 are aligned, and an electrical signal is transmitted through each probe 11, so that a state of the electrical connection of the wafer 21 can be inspected. That is, the probe head 1 holds a plurality of probes, each of the probes having a base end electrically connected to the printed circuit board 4 and a tip end in contact with an object to be inspected (pad 21a of the wafer 21).

The probe head 1 includes a side surface member 1a, an upper surface member 1b, a lower surface member 1c, and an intermediate member 1d, and the inside of the probe head 1 has a hollow structure. A plurality of through holes through which the probes 11 are inserted is formed in the upper surface member 1b, the lower surface member 1c, and the intermediate member 1d.

For example, during the manufacture of a probe card, the probes 11 are inserted into through-holes in the upper surface member 1b, the lower surface member 1c, and the intermediate member 1d that are aligned in the vertical direction. Thereafter, the upper surface member 1b, the lower surface member 1c, and the intermediate member 1d are moved relative to each other in a direction that crosses the vertical direction (which may be referred to as a horizontal direction in the following description) to hold the plurality of probes 11. The tip end of each probe 11 is connected to each pad 21a of the wafer 21 as an object to be inspected.

The space transformer 2 is interposed between the printed circuit board 4 and the probe head 1, and converts a wiring pitch of the base end of each probe 11 held by the probe head 1. The lower surface of the space transformer 2 is in contact with the base end of the probe 11. The upper surface of the space transformer 2 faces the printed circuit board 4 across the interposer 3. The interposer 3 is a substrate for conducting the upper surface and the lower surface, and electrically connects a wiring 2a arranged in the space transformer 2 and the printed circuit board 4 with a contact 3b as illustrated in FIG. 2. As the contact 3b, an elastic member such as a pogo pin or conductive rubber can be used. It is noted that the contact 3b is not limited to an elastic member, and wiring may be used.

As illustrated in FIG. 1, positioning pins 8 are provided between the probe head 1 and the space transformer 2. Specifically, the positioning pins 8 extending in the vertical direction are provided so that they penetrate from the lower surface of the probe head 1 to the upper surface of the space transformer 2. Four positioning pins 8 are provided, for example. That is, the positioning pins 8 connect the space transformer 2 and the probe head 1. The positioning pins 8 are provided, so that the probe head 1 and the space transformer 2 can be fixed without being displaced.

The positioning pins 8 may be provided to be positioned, for example, in a hollow portion 6a of the guide plate 6 (see FIG. 3 described later). Through holes for the positioning pins 8 may be formed in the guide plate 6, and the positioning pins 8 may be provided to be positioned in the through holes.

As illustrated in FIGS. 1 and 2, a plurality of lands 3a is provided on an upper surface of the interposer 3, and are electrically connected to terminals exposed on a lower surface of the printed circuit board 4. The terminals connected to the lands 3a are drawn out on an upper surface of the reinforcing plate 5 through wirings 4a. A multimeter (not illustrated) is connected to a terminal on the upper surface of the reinforcing plate 5 and an electrical signal is output by the multimeter, so that a status of the electrical connection of the wafer can be inspected.

As illustrated in FIG. 3, the guide plate 6 is a hexagonal flat plate. A hexagonal hollow portion 6a is formed at a center of the guide plate 6. The hollow portion 6a is formed below the space transformer 2 having a rectangular shape at a position overlapping with a region connected to the probe 11 of the space transformer 2.

Protrusions p are formed at three positions around the hollow portion 6a on the surface (upper surface) of the guide plate 6. As illustrated in FIG. 2, each protrusion p is hemispherical in shape, and an apex of each protrusion p is in contact with the lower surface (first surface) of the space transformer 2. That is, the space transformer 2 and the guide plate 6 are in point contact with each other by three protrusions p (a plurality of protrusions). The guide plate 6 is provided on a side of the probe head of the space transformer 2 and supports the lower surface (first surface) of the space transformer 2.

Lower ends of bolts 7 (connecting members) extending in a vertical direction are connected to three positions around the guide plate 6. The upper ends of the bolts 7 are fixed to the upper surface of the reinforcing plate 5 (see FIG. 1). Accordingly, the guide plate 6 is fixed to the reinforcing plate 5 and the printed circuit board 4. A bolt 7 is an example of a connecting member that penetrates the printed circuit board 4 to connect and fix the guide plate 6.

The protrusions p are formed in the same number as the bolts 7, and may be provided inside of the bolts 7. That is, in FIG. 3, each bolt 7 is arranged to be located at an apex of a triangle, and each protrusion p is arranged to be located at an apex of a triangle smaller than the said triangle. That is to say, connecting members are bolts 7 connected to the guide plate 6 through the printed circuit board 4 and arranged on an outer peripheral side of the protrusions p. The bolts 7 are provided in the same number as the protrusions p. The number of protrusions p is not limited to the same number as the bolt 7.

Next, the operation and effect of the electrical connection device 100 according to the embodiment configured as described above will be described. When inspecting the electrical characteristics of the wafer 21 to be inspected, the tip end of each probe 11 held on the probe head 1 is connected to each pad 21a formed on the wafer 21.

As described above, the space transformer 2 and the guide plate 6 are in point contact with each other by the protrusions p arranged at three locations. Therefore, the space transformer 2 can move in a plane direction relative to the guide plate 6 and the printed circuit board 4 when the probes 11 and the pads 21a are aligned. The space transformer 2 and the probe head 1 are connected by the positioning pins 8, so that the probes 11 and the pads 21a of the wafer 21 can be positioned with high accuracy.

Furthermore, it is not necessary to position the space transformer 2 with high accuracy during attachment to the printed circuit board 4 since the space transformer 2 can be moved in the plane direction relative to the guide plate 6. Therefore, efforts by users can be reduced. The space transformer 2 can be moved in the plane direction to prevent misalignment even when the wafer 21 expands due to heat.

In the embodiment, the protrusions p are provided inside of the bolts 7 arranged at three locations as illustrated in FIG. 3. Therefore, by adjusting the expansion and contraction of the bolts 7 illustrated in FIGS. 1 and 2, the protrusions p corresponding to respective bolts 7 can be moved in the vertical direction to support the space transformer 2 in a way that suits senses of an operator. If the guide plate 6 is positioned obliquely to the plane direction (for example, in the horizontal direction), the space transformer 2 is also positioned obliquely to the horizontal direction. As a result, the probe head 1 is also positioned obliquely to the horizontal direction, and the tip end of the probe 11 is not orthogonal to the horizontal direction. Therefore, it is possible that a problematic contact failure occurs. In the embodiment, such a problem can be avoided since the guide plate 6 can be set in the horizontal direction by adjusting the bolts 7 in the vertical direction.

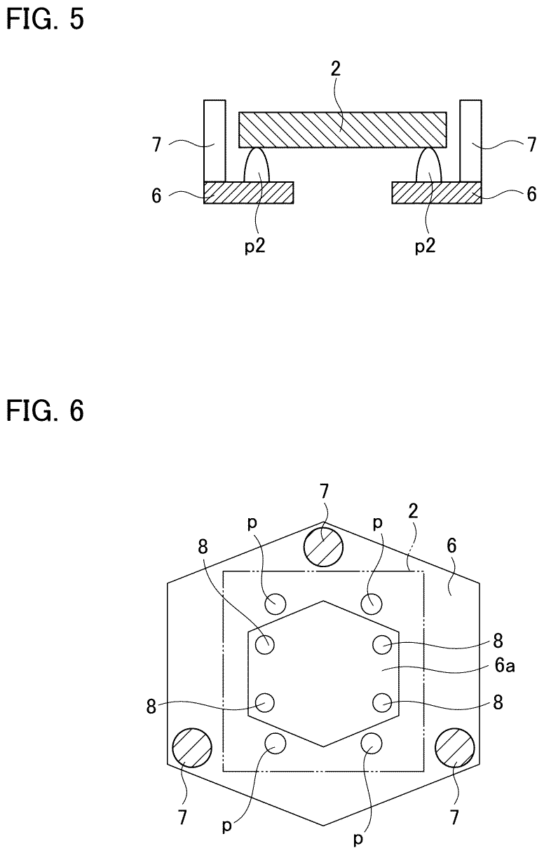

In the embodiment, the protrusions p that are hemispherical in shape as illustrated in FIG. 2 are described as an example, but ball bearing-like protrusions p1 as illustrated in FIG. 4 or longitudinal protrusions p2 as illustrated in FIG. 5 may be used, for example.

An example of arranging the protrusions p in three locations is described in the embodiment, as illustrated in FIG. 3, but the protrusions p may be arranged in four or more locations as illustrated in FIG. 6. An example of using a hexagonal guide plate 6 is described in the embodiment, as illustrated in FIG. 3, but the shape of the guide plate 6 is not limited to a hexagon and may be, for example, a square.

### DESCRIPTION OF MODIFIED EXAMPLE

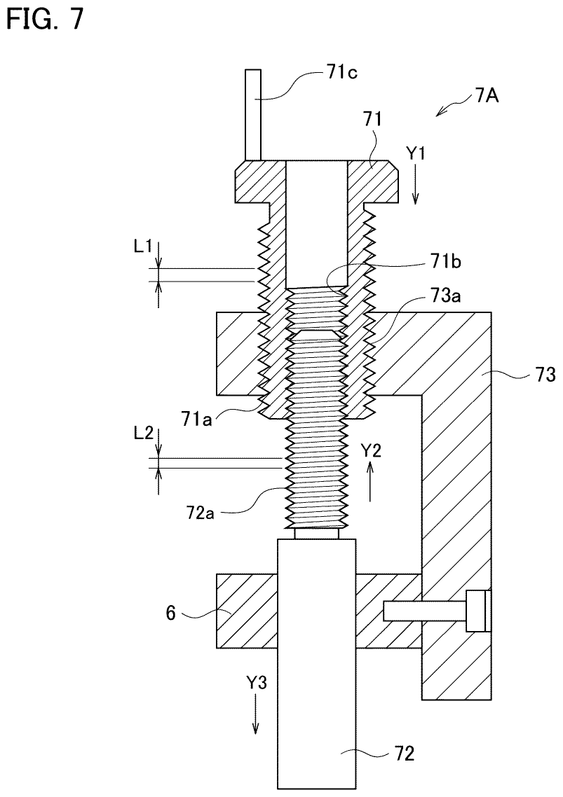

FIG. 7 is a cross-sectional view illustrating a modified example of the bolt 7 described in the embodiment. A bolt 7A according to the modified example includes an outer screw 71 and an inner screw 72 screwed to the outer screw 71.

A screw thread 71a of the outer screw 71 is screwed to a female screw 73a formed in a bracket 73 having an inverted L-shaped cross section and connected to the guide plate 6. Pitch of the screw thread 71a is L1. A female screw part 71b is formed inside the outer screw 71. The pitch of the female screw 71b is set to L2 (L2<L1).

A handle 71c is provided at a top of the outer screw 71. A user can operating the handle 71c to rotate the outer screw 71.

The inner screw 72 is fixed to the guide plate 6. The inner screw 72 extends in a vertical direction to the guide plate 6. Pitch of a thread 72a of the inner screw 72 is L2. The thread 72a of the inner screw 72 is screwed to the female screw 71b formed in the outer screw 71. That is, the bolt 7A is a differential screw capable of adjusting a distance between the guide plate 6 and the printed circuit board 4. The printed circuit board 4 and the reinforcing plate 5 illustrated in FIG. 1 are provided between the top of the external screw 71 and the guide plate 6, but they are not illustrated in FIG. 7.

In the bolt 7A configured as described above, when the user operates the handle 71c to rotate the external screw 71, the external screw 71 is turned once, and the external screw 71 moves by pitch L1 in a downward direction (a direction of Y1 in FIG. 7).

The female screw 71b formed inside the external screw 71 rotates with respect to the screw thread 72a of the internal screw 72, so that the internal screw 72 moves by pitch L2 in an upward direction (a direction of Y2 in FIG. 7). That is, when the user turns the handle 71c once, the distance between the printed circuit board 4 and the guide plate 6 can be changed (increased or decreased) by a distance (L1−L2). Thus, the position of the guide plate 6 can be finely adjusted in the vertical direction.

The printed circuit board 4 and the guide plate 6 are connected by use of the bolt 7A according to the modified example, so that the position of the guide plate 6 relative to the printed circuit board 4 can be finely adjusted in the vertical direction. As a result, pressure can be adjusted as appropriate when the protrusions p and the space transformer 2 contact with each other.

Although the present invention has been described in accordance with the embodiments described above, the description and drawings forming a part of the present invention should not be understood as limiting the present invention. The present disclosure will reveal various alternative embodiments, examples and operational techniques to those skilled in the art.

What is claimed is:

1. A space transformer support structure that supports a space transformer interposed between a printed circuit board and a probe head, comprising:
a guide plate provided on a side of the probe head of the space transformer and supporting a first surface of the space transformer; and
connecting members that fix the guide plate to the printed circuit board, wherein
a plurality of protrusions in point contact with the first surface of the space transformer is provided on the surface of the guide plate.

2. The space transformer support structure according to claim 1, further comprising positioning pins that connect the space transformer and the probe head.

3. The space transformer support structure according to claim 1, wherein each protrusion is hemispherical in shape at a tip end.

4. The space transformer support structure according to claim 1, wherein the connecting members are bolts connected to the guide plate through the printed circuit board and arranged on an outer peripheral side of the protrusions.

5. The space transformer support structure according to claim 4, wherein the bolts are provided in the same number as the protrusions.

6. An electrical connection device, comprising:
a printed circuit board;
a probe head that holds a plurality of probes, each of the probes having a base end electrically connected to the printed circuit board and a tip end contacted with an object to be inspected;
a space transformer interposed between the printed circuit board and the probe head and converting a wiring pitch of each of the probes;
a guide plate provided on a side of the probe head of the space transformer and supporting a first surface of the space transformer; and
connecting members that fix the guide plate to the printed circuit board, wherein
a plurality of protrusions in point contact with the first surface of the space transformer is provided on the surface of the guide plate.
